(19) United States
(12) Patent Application Publication
(10) Pub. No.: US 2026/0087988 A1
(43) Pub. Date: Mar. 26, 2026

(54) DISPLAY DEVICE

(71) Applicant: LG Display Co., Ltd., Seoul (KR)

(72) Inventors: Ki Tae KWON, Gyeonggi-do (KR); Jong Wook JANG, Gyeonggi-do (KR); Dae Ho PARK, Gyeonggi-do (KR)

(21) Appl. No.: 19/306,758

(22) Filed: Aug. 21, 2025

(30) Foreign Application Priority Data
Sep. 25, 2024 (KR) 10-2024-0129862

(51) Int. Cl. G09G 3/3233; G09G 3/20; G09G 3/3266; H10K 59/131

(52) U.S. Cl. CPC G09G 3/3233; G09G 3/3266; H10K 59/131; G09G 3/2007; G09G 2300/0819; G09G 2300/0842; G09G 2310/0286; G09G 2310/08; G09G 2320/0223; G09G 2320/0247; G09G 2330/021; G09G 2380/10

(57) ABSTRACT

A display device includes a pixel array in which a plurality of data lines, a plurality of gate lines, and a plurality of pixel circuits are arranged; a data driver configured to output a data voltage to the plurality of data lines; a gate driver configured to sequentially output gate signals to the plurality of gate lines; a common line configured to simultaneously apply a common gate signal to the plurality of gate lines; and a timing controller configured to generate the common gate signal.

### CROSS-REFERENCE TO RELATED APPLICATION

Pursuant to 35 U.S.C. § 119 (a), this application claims the benefit of an earlier filing date and right of priority to Korean Patent Application No. 10-2024-0129862, filed Sep. 25, 2024, the disclosure of which is incorporated herein by reference in its entirety.

### TECHNICAL FIELD

The present invention relates to a display device.

### BACKGROUND

As the market for future vehicles such as electric vehicles and self-driving cars expands, demand for vehicle display devices is rapidly increasing. In vehicle display devices, display panels using organic light emitting display devices are attracting attention.

### SUMMARY

A display device according to implementations of the present disclosure may include a pixel array in which a plurality of data lines, a plurality of gate lines, and a plurality of pixel circuits are arranged; a data driver configured to output a data voltage to the plurality of data lines; a gate driver configured to sequentially output gate signals to the plurality of gate lines; a common line configured to apply (e.g., simultaneously) a common gate signal to the plurality of gate lines; and a timing controller configured to generate the common gate signal.

A display device according to implementations of the present disclosure may include a pixel array in which a plurality of data lines, a plurality of gate lines, and a plurality of pixel circuits are arranged; a data driver configured to output a data voltage to the plurality of data lines; a gate driver configured to sequentially output gate signals to the plurality of gate lines; a common line configured to apply (e.g., simultaneously) a common gate signal to the plurality of gate lines; and a power supply configured to generate the common gate signal.

### BRIEF DESCRIPTION OF THE DRAWINGS

The above and other objects, features, and advantages of the present disclosure will become more apparent to those of ordinary skill in the art by describing exemplary implementations thereof in detail with reference to the attached drawings.

FIGS. 1A to 1C are block diagrams showing a display device according to an implementation of the present disclosure.

FIGS. 2A to 2B are diagrams showing a configuration of a gate driver according to an implementation of the present disclosure.

FIGS. 3A to 3B are diagrams showing a first gate driver according to an implementation of the present disclosure.

FIGS. 4A to 4B are diagrams showing wirings arranged in the gate driver according to an implementation.

FIG. 5 is a diagram showing a pixel circuit according to a first implementation of the present disclosure.

FIG. 6 is a diagram showing driving timings of gate signals applied to the pixel circuit of FIG. 5.

FIG. 7 is a diagram showing a pixel circuit according to a second implementation of the present disclosure.

FIGS. 8A to 8B are diagrams showing driving timings of gate signals applied to the pixel circuit of FIG. 7.

FIGS. 9A to 9G are diagrams for explaining the output principle of gate signals according to an implementation of the present disclosure.

FIGS. 10 to 15 are diagrams for explaining the gate signal application principle according to an implementation.

FIGS. 16 to 17 are diagrams showing improvement in FFR performance according to an implementation of the present disclosure.

### DETAILED DESCRIPTION

An organic light emitting display device includes an organic light emitting diode (hereinafter, referred to as “OLED”) that emits light by itself, and has advantages of fast response speed, high luminous efficiency, brightness, and wide viewing angle. The organic light emitting display device has a fast response speed, is excellent in terms of luminous efficiency, luminance and viewing angle, and provides an excellent contrast ratio and color reproducibility since it may express the black grayscale in complete black.

Because the display panel of an organic light emitting display device may be flexibly bent, it may easily implement a curved surface. Due to these advantages, organic light emitting display devices have broad applicability in the vehicle display device market.

A vehicle display device can include a display panel including a plurality of pixels and a driver configured to output a driving signal for driving the display panel. The driver can include a gate driver configured to supply gate signals such as a scan signal and an emission control signal to the display panel, and a data driver configured to supply data signals to the display panel.

When a circuit of the gate driver is arranged in a non-display area, a problem can arise where a bezel of the display panel increases in size. In contrast, when the circuit of the gate driver is arranged between pixels in a display area, the bezel size can be reduced, but this can create another problem where a design margin of the pixels decreases. Accordingly, there is a need for a solution capable of securing a pixel design margin while realizing a narrow bezel of the display panel.

Implementations of the present disclosure can provide a display device capable of achieving a narrow bezel.

It should be noted that objects of the present disclosure are not limited to the above-described objects, and other objects of the present disclosure will be apparent to those skilled in the art from the following descriptions.

The present disclosure can implement a narrow bezel of a display panel and secure a pixel design margin by not including at least one of a plurality of gate drivers that generate gate signals and instead applying (e.g., simultaneously) a predetermined common gate signal to all pixels through a common line.

The present disclosure can improve image quality degradation that may be caused by variation in pixel driving voltage by applying (e.g., simultaneously) a predetermined common gate signal to all pixels through a common line.

The present disclosure can enable low-power operation because power consumption can be reduced.

The effects of the present specification are not limited to the above-mentioned effects, and other effects that are not mentioned will be apparently understood by those skilled in the art from the following description and the appended claims.

Advantages and features of the present specification and methods of achieving them will become apparent with reference to preferable implementations, which are described in detail, in conjunction with the accompanying drawings. However, the present specification is not limited to the implementations to be described below and may be implemented in different forms, the implementations are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the implementations of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted.

When ‘including,’ ‘having,’ ‘consisting,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

The same reference numerals may refer to substantially the same elements throughout the present disclosure.

The following implementations can be partially or entirely bonded to or combined with each other and can be linked and operated in technically various ways. The implementations can be carried out independently of or in association with each other.

Hereinafter, various implementations of the present disclosure will be described in detail with reference to the accompanying drawings.

In a display device of the present disclosure, the pixel circuit and the gate driving circuit may include a plurality of transistors. Transistors may be implemented as oxide thin film transistors (oxide TFTs) including an oxide semiconductor, low temperature polysilicon (LTPS) TFTs including low temperature polysilicon, or the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons may flow from a source to a drain. The n-channel transistor has a direction of a current flowing from the drain to the source. In the case of a p-channel transistor (p-channel metal-oxide semiconductor (PMOS), since carriers are holes, a source voltage is higher than a drain voltage such that holes may flow from a source to a drain. In the p-channel transistor, since holes flow from the source to the drain, a current flows from the source to the drain. It should be noted that a source and a drain of a transistor are not fixed. For example, a source and a drain may be changed according to an applied voltage. Therefore, the disclosure is not limited due to a source and a drain of a transistor. In the following description, a source and a drain of a transistor will be referred to as a first electrode and a second electrode.

A gate signal swings between a gate-on voltage and a gate-off voltage. The gate-on voltage is set to a voltage higher than a threshold voltage of a transistor, and the gate-off voltage is set to a voltage lower than the threshold voltage of the transistor.

The transistor is turned on in response to the gate-on voltage and is turned off in response to the gate-off voltage. In the case of the n-channel transistor, a gate-on voltage may be a gate high voltage, and a gate-off voltage may be a gate low voltage. In the case of the p-channel transistor, a gate-on voltage may be a gate low voltage, and a gate-off voltage may be a gate high voltage.

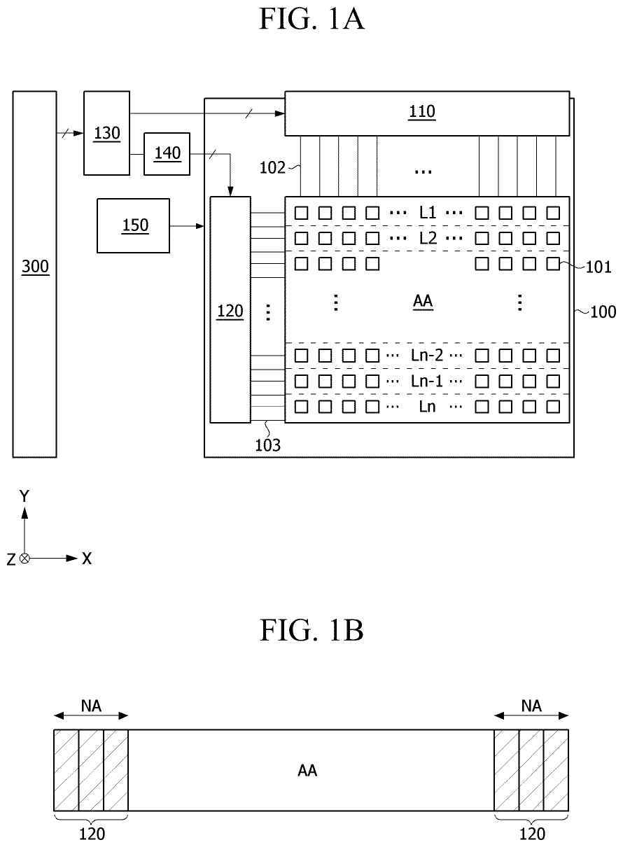

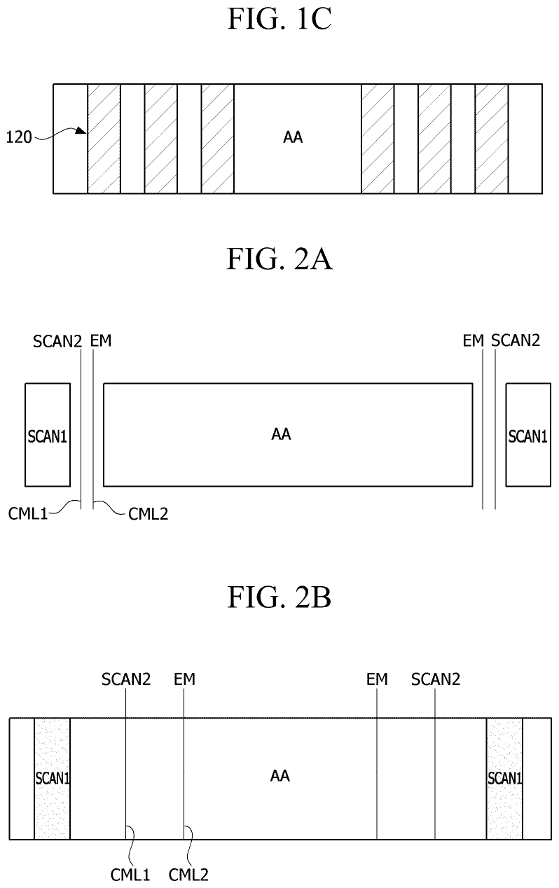

FIGS. 1A to 1C are block diagrams showing a display device according to an implementation of the present disclosure.

Referring to FIGS. 1A to 1C, the display device according to an implementation of the present disclosure includes a display panel 100, and a display panel driving circuit for writing pixel data to pixels of the display panel 100. Additionally, the display device includes a power supply 150.

The display panel 100 may be, but not limited to, a panel having a rectangular structure with a length in the X-axis direction, a width in the Y-axis direction, and a thickness in the Z-axis direction. For example, the display panel 100 may be a heterogeneous panel of which at least a portion is curved or elliptical.

The display area AA of the display panel 100 includes a pixel array to display an input image. The pixel array includes a plurality of data lines 102, a plurality of gate lines 103 crossing the data lines 102, and pixels arranged in a matrix form. The display panel 100 may further include power lines commonly connected to the pixels. The power lines may be commonly connected to pixel circuits to supply a voltage required for driving pixels 101 to the pixels 101.

Each of the pixels 101 may be divided into a red sub-pixel, a green sub-pixel, and a blue sub-pixel for color implementation. Each pixel may further include a white sub-pixel. Each sub-pixel includes a pixel circuit for driving a light emitting element. The light emitting element may include an OLED or an inorganic light emitting diode (LED). Each pixel circuit is connected to the data lines, the gate lines, and the power lines. In the following description, a pixel may be interpreted as a sub-pixel.

The display area AA includes a plurality of pixel lines L1 to Ln. Each of the pixel lines L1 to Ln includes one line of pixels arranged along the line direction (X-axis direction) in the pixel array of the display panel 100. Those pixels arranged in one pixel line share the gate lines 103. The sub-pixels arranged in the column direction Y along the data line direction share the same data line 102. One horizontal period is a time obtained by dividing one frame period by the total number of pixel lines L1 to Ln.

The display panel 100 may be implemented with a non-transmissive display panel or a transmissive display panel. The transmissive display panel may be applied to a transparent display device in which an image is displayed on the screen and a real object in the background is visible. The display panel 100 may be made of a flexible display panel.

The power supply 150 receives an input voltage applied from the host system 300 and outputs a voltage needed to drive the pixels 101 of the display panel 100 and the display panel driving circuit. To this end, the power supply 150 may include a direct current to direct current converter (DC-DC converter). The DC-DC converter may include a charge pump, a regulator, a buck converter, a boost converter, and the like. The power supply 150 may output a constant voltage (or direct current voltage), such as gate-on voltage, gate-off voltage, pixel driving voltage, cathode voltage, reference voltage, IC driving voltage of the display panel driving circuit, through the DC-DC converter. The gate-on voltage and the gate-off voltage may be supplied to the level shifter 140 and the gate driver 120. Voltages such as pixel driving voltage, cathode voltage, and reference voltage may be supplied to the pixels 101 through the power lines commonly connected to the pixels 101.

The power supply 150 may further include a gamma voltage generator. The gamma voltage generator receives a high-potential reference voltage and a low-potential reference voltage and outputs a plurality of gamma reference voltages divided at specific intervals on a preset gamma curve, for example, a 2.2 gamma curve. The gamma reference voltages are supplied to the data driver 110. In the data driver 110, the gamma reference voltages are subdivided by a voltage dividing circuit into grayscale voltages.

The gamma voltage generator may be implemented with a programmable gamma circuit that may adjust the voltage of each of the gamma reference voltages according to digital data. The timing controller 130, the host system 300, or a separate external device may update digital data stored in a register of the programmable gamma circuit through a communication interface.

The display panel driving circuit writes pixel data of the input image to the pixels 101 of the display panel 100 under the control of the timing controller 130. The display panel driving circuit includes a data driver 110 and a gate driver 120.

The display panel driving circuit may further include a touch sensor driver for driving touch sensors. The data driver 110 and the touch sensor driver may be integrated into one source drive IC.

The data driver 110 receives pixel data of the input image as a digital signal from the timing controller 130 and outputs a data voltage. The data driver 110 may receive gamma reference voltages and generate gamma compensation voltages for each grayscale through a voltage dividing circuit. The per-grayscale gamma compensation voltages are supplied to a digital to analog converter (hereinafter referred to as “DAC”) disposed in each channel of the data driver 110.

The data driver 110 samples and latches digital data received from the timing controller 130 and then inputs the digital data to the DAC. Here, the digital data includes pixel data of the input image. Additionally, the digital data may include mode selection data for selecting first mode and second mode. The DAC converts the pixel data into a gamma compensation voltage and outputs a data voltage of the pixel data.

The gate driver 120 may be formed on the display panel 100 together with the circuit elements and wiring lines of the display area AA. The gate driver 120 may be disposed in at least one of left and right non-display areas NA outside the display area AA in the display panel 100 or at least a part thereof may be disposed within the display area AA.

The gate driver 120 sequentially outputs pulses of the gate signals to the gate lines 103 under the control of the timing controller 130. The gate driver 120 may sequentially supply the gate signals to the gate lines 103 by shifting the pulses of the gate signals using shift registers. When a plurality of gate signals are applied to each pixel, the gate driver 120 may include a plurality of shift registers. The gate signal may include a scan signal being input to the pixel circuit through a plurality of gate lines, and an emission signal (or EM signal).

The gate driver 120 may be arranged in a non-display area in a gate in panel (GIP) manner, or may be arranged between sub-pixels SP in a display area AA in a gate in active area (GIA) manner. For example, as shown in FIG. 1B, a circuit of the gate driver 120 may be arranged in a non-display area NA, or as shown in FIG. 1C, a circuit of the gate driver 120 may be arranged between pixels in the display area AA.

The timing controller 130 receives digital video data of an input image and a timing signal synchronized with this data from the host system 300. The timing signal may include a vertical synchronization signal Vsync, a horizontal synchronization signal Hsync, and a data enable signal DE. Since the vertical period and horizontal period may be determined by counting the data enable signal DE, the vertical synchronization signal Vsync and the horizontal synchronization signal Hsync may be omitted. The horizontal synchronization signal Hsync and the data enable signal DE have a periodicity of 1 horizontal period (1H).

The timing controller 130 may control the display panel driving circuit by generating a data timing control signal for controlling the operation timing of the data driver 110 and a gate timing control signal for controlling the operation timing of the gate driver 120 based on the timing signals Vsync, Hsync, DE received from the host system 300. The timing controller 130 may synchronize the data driver 110 and the gate driver 120 by controlling the operation timing of the display panel driving circuit.

The gate timing control signal output from the timing controller 130 may be input to the shift register of the gate driver 120 through the level shifter 140. The level shifter 140 may convert a voltage of the gate timing control signal received from the timing controller 130 to a swing width between the gate-on voltage and the gate-off voltage and supply it to the gate driver 120.

The timing controller 130 may analyze the input image for each frame and generate a control signal for selectively outputting gate signals according to the analysis result. The generated control signal may be provided to the shift register of the gate driver 120 through the level shifter 140.

The host system 300 may include a main board of one of a television system, a set-top box, a navigation system, a personal computer (PC), a vehicle system, a mobile terminal, and a wearable terminal. The host system 300 may scale an image signal from a video source according to the resolution of the display panel 100, and may transmit it to the timing controller 130 together with the timing signals.

In implementations, it is intended to apply (e.g., simultaneously) a common gate signal to all pixels through a common line without including at least one of a plurality of gate drivers that generate gate signals.

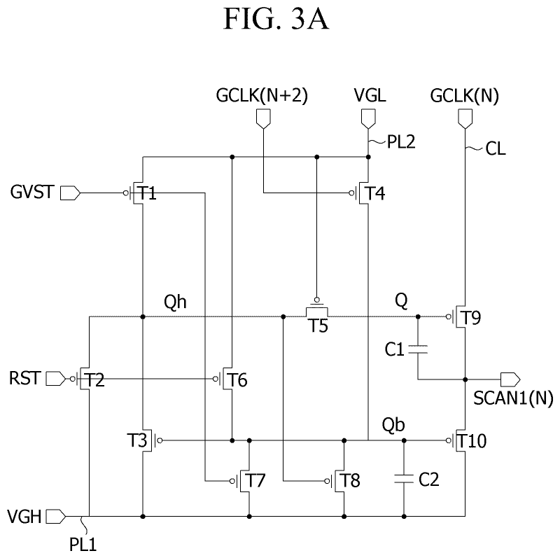

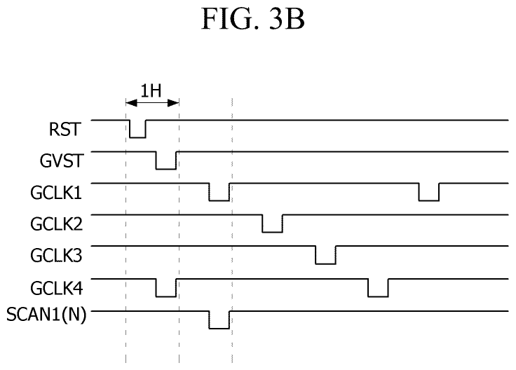

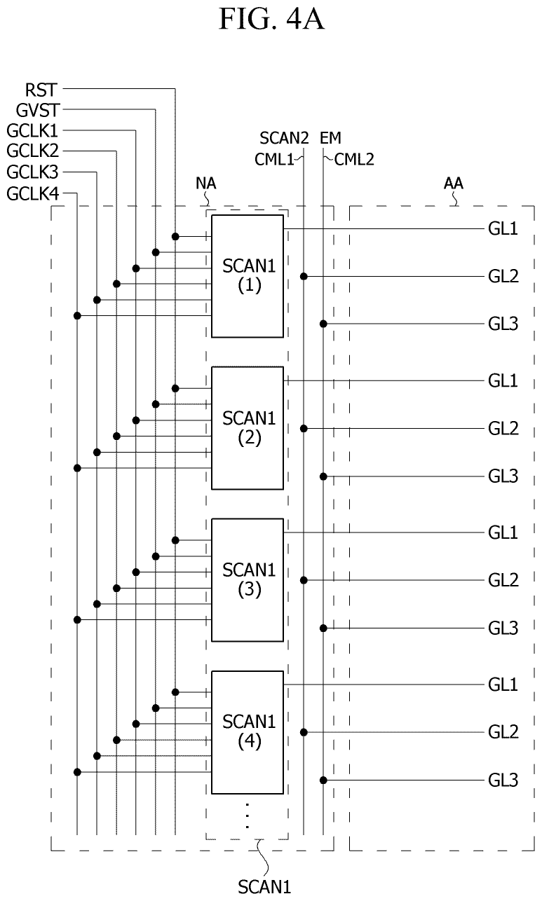

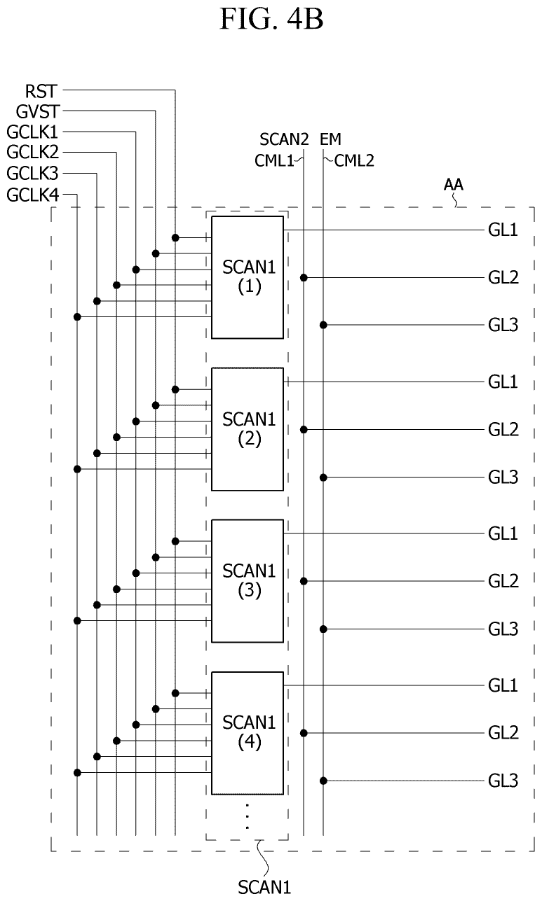

FIGS. 2A to 2B are diagrams showing a configuration of a gate driver according to an implementation of the present disclosure, FIGS. 3A to 3B are diagrams showing a first gate driver according to an implementation of the present disclosure, and FIGS. 4A to 4B are diagrams showing wirings arranged in the gate driver according to an implementation.

Referring to FIGS. 2A to 2B, a gate driver according to an implementation of the present disclosure may include a first gate driver that outputs a first gate signal, a first common line CML1 that commonly applies a second gate signal or a first common gate signal, and a second common line CML2 that commonly applies a third gate signal or a second common gate signal.

The first gate signal may be sequentially output for each pixel line through the first gate driver. The first common gate signal may be applied (e.g., simultaneously) to all pixels through the first common line CML1, and the second common gate signal may be applied (e.g., simultaneously) to all pixels through the second common line CML2.

Here, the first gate signal may be a first scan signal SCAN1, the first common gate signal may be a second scan signal SCAN2, and the second common gate signal may be an EM signal EM, but is not limited thereto.

As described above, in an implementation, since each of the first common gate signal and the second common gate signal is applied (e.g., simultaneously) through a single common line, in a structure such as FIG. 2A, the bezel size of the display panel may be reduced, and in a structure such as FIG. 2B, a pixel design margin may be secured.

Referring to FIG. 3A, a first gate driver according to an implementation of the present disclosure may include a first transistor T1, a second transistor T2, a third transistor T3, a fourth transistor T4, a fifth transistor T5, a sixth transistor T6, a seventh transistor, an eighth transistor, a ninth transistor or a pull-up transistor T9, a tenth transistor or a pull-down transistor T10, a first capacitor C1, and a second capacitor C2.

The first transistor T1 is turned on by a start signal GVST or a previous carry signal C(n−1), and connects a first node Qh to a second power line PL2 to which a low-potential voltage is applied. The first transistor T1 includes a gate electrode to which the previous carry signal C(n−1) is applied, a first electrode connected to the first node Qh, and a second electrode connected to the second power line PL2.

The second transistor T2 is turned on by a voltage of a reset signal RST and connects the first node Qh to a first power line PL1 to which a high-potential voltage VGH is applied. The second transistor T2 includes a gate electrode to which the reset signal RST is applied, a first electrode connected to the first node Qh, and a second electrode connected to the first power line PL1.

The third transistor T3 is turned on by a voltage of a second control node Qb and connects the second control node Qb to the first power line PL1 to which a high-potential voltage VGH is applied. The third transistor T3 includes a gate electrode connected to the second control node Qb, a first electrode connected to the first node Qh, and a second electrode connected to the first power line PL1.

The fourth transistor T4 is turned on by a voltage of a next clock signal GCLK (N+2) and connects the second control node Qb to the second power line PL2. The fourth transistor T4 includes a gate electrode to which a next clock signal GCLK (N+2) is applied, a first electrode connected to the second power line PL2, and a second electrode connected to the second control node Qb.

The fifth transistor T5 is turned on by a low-potential voltage VGL and connects the first node Qh to a first control node Q. The fifth transistor T5 includes a gate electrode connected to the second power line PL2, a first electrode connected to the first node Qh, and a second electrode connected to the first control node Q.

The sixth transistor T6 is turned on by a voltage of a reset signal RST and connects the second control node Qb to the second power line PL2. The sixth transistor T6 includes a gate electrode to which the reset signal RST is applied, a first electrode connected to the second power line PL2, and a second electrode connected to the second control node Qb.

The seventh transistor T7 is turned on by a start signal GVST or a previous carry signal C(n−1) and connects the second control node Qb to the first power line PL1. The seventh transistor T7 includes a gate electrode to which the previous carry signal C(n−1) is applied, a first electrode connected to the first node Qh, and a second electrode connected to the first power line PL1.

The eighth transistor T8 is turned on by a voltage of the first node Qh and connects the second control node Qb to the first power line PL1. The eighth transistor T8 includes a gate electrode connected to the first node Qh, a first electrode connected to the second control node Qb, and a second electrode connected to the first power line PL1.

The ninth transistor T9 is turned on by a voltage of the first control node Q and outputs a clock signal GCLK (N) to an output node OUT. The ninth transistor T9 includes a gate electrode connected to the first control node Q, a first electrode connected to a clock line CL to which a clock signal GCLK (N) is applied, and a second electrode connected to an output node OUT.

The tenth transistor T10 is turned on by a voltage of the second control node Qb and outputs a high-potential voltage VGH to the output node OUT. The tenth transistor T10 includes a gate electrode connected to the second control node Qb, a first electrode connected to the output node OUT, and a second electrode connected to the first power line PL1.

The first capacitor C1 is connected between the gate electrode and the second electrode of the ninth transistor T9. The second capacitor C2 is connected between the gate electrode and the second electrode of the tenth transistor T10.

The gate driver may output a gate signal in synchronization with a clock signal, as shown in FIG. 3B. For example, when using four-phase clock signals GCLK1, GCLK2, GCLK3, and GCLK4, the gate driver outputs the gate signal in synchronization with the clock signal GCLK1.

Referring to FIGS. 4A to 4B, in an area where the gate driver according to an implementation of the present disclosure is arranged, a first gate driver SCAN1 that outputs a first gate signal SCAN1(N), wirings that apply a start signal GVST, four-phase clock signals GCLK1, GCLK2, GCLK3, and GCLK4, and a reset signal RST to respective signal transmission parts of the first gate driver SCAN1, a first common line CML1 that commonly applies a first common gate signal SCAN2, and a second common line CML2 that commonly applies a second common gate signal EM may be arranged.

The first gate signal output from the first gate driver SCAN1, the first common gate signal applied through the first common line CML1, and the second common gate signal applied through the second common line CML2 may be provided to pixels through a plurality of gate lines GL1, GL2, and GL3.

As such, since the first common gate signal and the second common gate signal are applied through common lines, it becomes unnecessary to provide signal transmission parts for generating the first and second common gate signals and wirings for applying a start signal, clock signal, and reset signal to the signal transmission parts.

In this example, the first common gate signal and the second common gate signal are applied through common lines as the common gate signals, but it is not necessarily limited thereto.

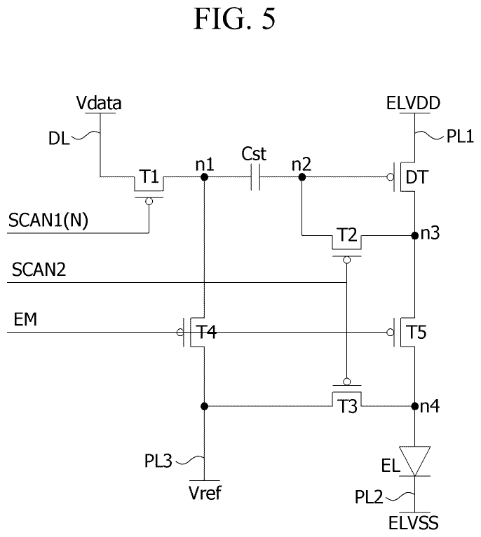

FIG. 5 is a diagram showing a pixel circuit according to a first implementation of the present disclosure.

Referring to FIG. 5, a pixel circuit according to a first implementation of the present disclosure includes a light-emitting element EL, a driving element DT that supplies current to the light-emitting element EL, a plurality of switch elements T1, T2, T3, T4, and T5 that switch a current path connected to the driving element DT, and a capacitor Cst that stores a gate-to-source voltage of the driving element DT. The driving element DT and the switch elements T1, T2, T3, T4, and T5 may be implemented as P-channel TFTs.

The pixel circuit is connected to power lines, to which direct current (DC) voltages or constant voltages are applied, such as a pixel driving voltage line or a first power line PL1 to which the pixel driving voltage ELVDD is applied, a pixel base voltage line or a second power line PL2 to which the pixel base voltage ELVSS is applied, and a third power line PL3 to which a reference voltage Vref is applied. Power lines are connected may be commonly connected to all the pixels on the display panel.

The light-emitting element EL may be implemented as organic light-emitting diodes (OLEDs). The light-emitting element EL includes an anode, a cathode, and an organic compound layer formed between the anode and the cathode. The anode of the light-emitting element EL is connected to a fourth node n4, and the cathode thereof is connected to the second power line PL2 to which the pixel base voltage ELVSS is applied. The organic compound layer may include a hole injection layer HIL, a hole transport layer HTL, an emission layer EML, an electron transport layer ETL, and an electron injection layer EIL, but the present disclosure is not limited thereto. The light-emitting element EL may be implemented in a tandem structure in which a plurality of light-emitting layers are stacked. The light-emitting element EL of the tandem structure can improve the luminance and lifespan of the pixel.

The driving element DT generates current according to a gate-to-source voltage Vgs and drives the light-emitting element EL. The driving element DT includes a first electrode connected to a first power line PL1 to which a pixel driving voltage ELVDD is applied, a gate electrode connected to a second node n2, and a second electrode connected to a third node n3.

A first switch element T1 is connected between a data line DL and a first node n1. The first switch element T1 is turned on according to a gate-on voltage VGL of a first gate signal SCAN1(N) and applies a data voltage Vdata of pixel data to the first node n1. The first switch element T1 includes a first electrode connected to the data line DL, a gate electrode to which the second gate signal SCAN1(N) is applied, and a second electrode connected to the first node n1.

A second switch element T2 is connected between a second node n2 and a third node n3. The second switch element T2 is turned on according to a gate-on voltage VGL of a first common gate signal SCAN2 and connects the gate electrode and the second electrode of the driving element DT. The second switch element T2 includes a first electrode connected to the second node n2, a gate electrode to which the first common gate signal SCAN2 is applied, and a second electrode connected to the third node n3.

A third switch element T3 is connected between a fourth node n4 and a third power line PL3. The third switch element T3 is turned on according to a gate-on voltage VGL of the first common gate signal SCAN2 and connects the fourth node n4 to the third power line PL3 to which a reference voltage Vref is applied. The third switch element T3 includes a first electrode connected to the third power line PL3, a gate electrode to which the first common gate signal SCAN2 is applied, and a second electrode connected to the fourth node n4.

The fourth switch element T4 is connected between the first node n1 and the third power line PL3. The fourth switch element T4 is turned on according to a gate-on voltage VGL of the second common gate signal EM and connects the first node n1 to the third power line PL3. The fourth switch element T4 includes a first electrode connected to the first node n1, a gate electrode to which the second common gate signal EM is applied, and a second electrode connected to the third power line PL3.

A fifth switch element T5 is connected between the third node n3 and the fourth node n4. The fifth switch element T5 is turned on according to a gate-on voltage VGL of the second common gate signal EM and connects the third node n3 to the fourth node n4. The fifth switch element T5 includes a first electrode connected to the third node n3, a gate electrode to which the second common gate signal EM is applied, and a second electrode connected to the fourth node n4.

The capacitor Cst is connected between the first node n1 and the second node n2. The capacitor Cst maintains the gate-to-source voltage Vgs of the driving element DT during a light-emission period.

Gate signals applied to the pixel circuit of the first implementation include a first gate signal SCAN1(N), a first common gate signal SCAN2, and a second common gate signal EM. In the pixel circuit of the first implementation, the first common gate signal SCAN2 and the second common gate signal EM, excluding the first gate signal SCAN1(N), may be applied through common lines.

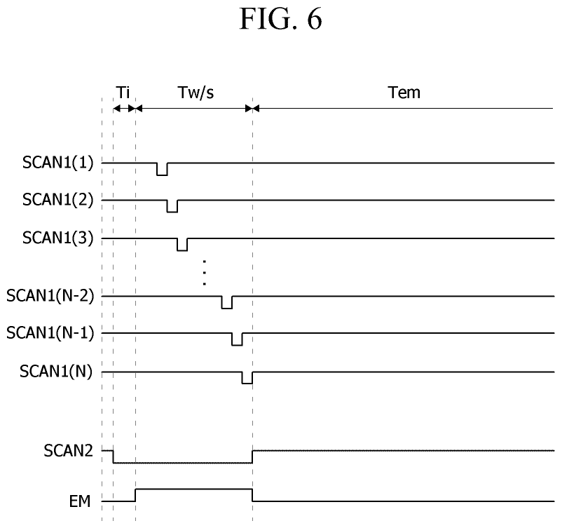

FIG. 6 is a diagram showing driving timings of gate signals applied to the pixel circuit of FIG. 5.

Referring to FIGS. 5 and 6, the pixel circuit according to an implementation of the present disclosure may be driven in the order of an initialization step Ti, a data writing and sensing step Tw/s, and a light-emission step Tem.

In the initialization step Ti, the first common gate signal SCAN2 having a gate-on voltage is applied (e.g., simultaneously) to all pixels through the first common line, and the second common gate signal EM having a gate-on voltage may be applied (e.g., simultaneously) to all pixels through the second common line.

In the data writing and sensing step Tw/s, the first gate signal SCAN1(1) to SCAN1(N) having a gate-on voltage is sequentially applied to each pixel line, and the threshold voltage of the driving element may be sensed.

In the light-emission step Tem, the second common gate signal EM having a gate-on voltage is applied (e.g., simultaneously) to all pixels through the second common line, and thereby all the pixels may simultaneously emit light.

As such, in an implementation, the first common gate signal SCAN2 for applying an initialization voltage Vref and the second common gate signal EM for causing the light-emitting elements to emit light, excluding the first gate signal SCAN1(N) for applying a data voltage Vdata to each pixel line, may be simultaneously applied to all pixels through the first common line and the second common line.

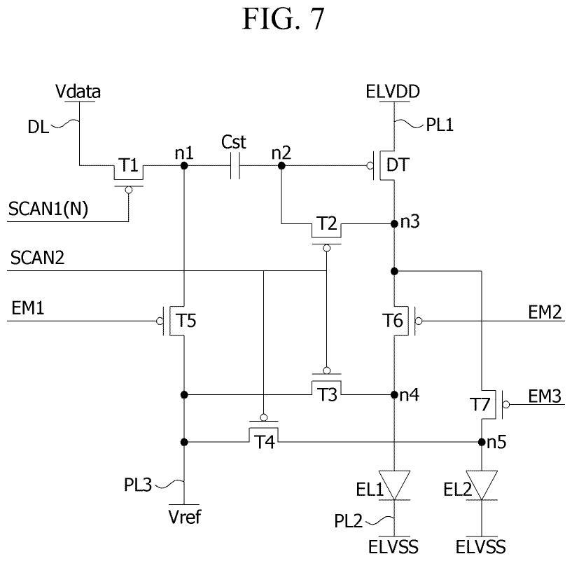

FIG. 7 is a diagram showing a pixel circuit according to a second implementation of the present disclosure.

Referring to FIG. 7, a pixel circuit according to the implementation includes a first light-emitting element EL1 that emits light in a first mode SMODE, a second light-emitting element EL2 that emits light in a second mode PMODE, a driving element DT that drives the first and second light-emitting elements EL1 and EL2, a plurality of switch elements T1 to T7 that switch current paths connected to the driving element DT, and a capacitor Cst. The driving element DT and the plurality of switch elements T1 to T7 may be implemented as p-channel transistors, but are not limited thereto.

The pixel circuit is connected to power lines to which direct current voltages or constant voltages are applied, such as a pixel driving voltage line or a first power line PL1 to which a pixel driving voltage ELVDD is applied, a pixel base voltage line or a second power line PL2 to which a pixel base voltage ELVSS is applied, and a reference voltage line or a third power line PL3 to which a reference voltage Vref is applied. On the display panel, the power lines may be commonly connected to all pixels.

The driving element DT generates current according to a gate-to-source voltage Vgs and drives the first and second light-emitting elements EL1 and EL2. The driving element DT includes a first electrode connected to a first power line PL1 to which a pixel driving voltage ELVDD is applied, a gate electrode connected to a second node n2, and a second electrode connected to a third node n3.

The first and second light-emitting elements EL1 and EL2 may be implemented as OLEDs. The light-emitting elements EL1 and EL2 include an anode electrode, a cathode electrode, and an organic compound layer formed between the electrodes. The anode electrode of the first light-emitting element EL1 is connected to a fourth node n4, and the cathode electrode is connected to a second power line PL2 to which a pixel base voltage ELVSS is applied. The anode electrode of the second light-emitting element EL2 is connected to a fifth node n5, and the cathode electrode is connected to the second power line PL2. The organic compound layer may include a hole injection layer (HIL), a hole transport layer (HTL), a light emission layer (EML), an electron transport layer (ETL), and an electron injection layer (EIL), but is not limited thereto. The light-emitting elements EL1 and EL2 may be implemented in a tandem structure in which a plurality of light-emitting layers are stacked. The light-emitting elements EL1 and EL2 having a tandem structure may improve the luminance and lifespan of the pixel.

In this case, a first lens may be arranged on the first light-emitting element EL1, and a second lens may be arranged on the second light-emitting element EL2. The first lens limits a vertical viewing angle of the first light-emitting element EL1 that emits light in the first mode, and the second lens may narrow a vertical viewing angle and a horizontal viewing angle of the second light-emitting element EL2. The first light-emitting element EL1 emits light in the first mode, but emits with a first viewing angle due to the first lens, and the second light-emitting element EL2 emits light in the second mode, but emits with a second viewing angle smaller than the first viewing angle due to the second lens.

A first switch element T1 is connected between a data line DL and a first node n1. The first switch element T1 is turned on according to a gate-on voltage VGL of the first gate signal SCAN1 and applies a data voltage Vdata of pixel data to a first node n1. The first switch element T1 includes a first electrode connected to a data line DL, a gate electrode to which the first gate signal SCAN1(N) is applied, and a second electrode connected to the first node n1.

A second switch element T2 is connected between a second node n2 and a third node n3. The second switch element T2 is turned on according to a gate-on voltage VGL of a first common gate signal SCAN2 and connects the gate electrode and the second electrode of the driving element DT. The second switch element T2 includes a first electrode connected to the second node n2, a gate electrode to which the first common gate signal SCAN2 is applied, and a second electrode connected to the third node n3.

A third switch element T3 is connected between a fourth node n4 and a third power line PL3. The third switch element T3 is turned on according to a gate-on voltage VGL of the first common gate signal SCAN2 and connects the fourth node n4 to the third power line PL3 to which a reference voltage Vref is applied. The third switch element T3 includes a first electrode connected to the third power line PL3, a gate electrode to which the first common gate signal SCAN2 is applied, and a second electrode connected to the fourth node n4.

The fourth switch element T4 is connected between the fifth node n5 and the third power line PL3. The fourth switch element T4 is turned on according to a gate-on voltage VGL of the first common gate signal SCAN2 and connects the fifth node n5 to the third power line PL3 to which a reference voltage Vref is applied. The fourth switch element T4 includes a first electrode connected to the third power line PL3, a gate electrode to which the first common gate signal SCAN2 is applied, and a second electrode connected to the fifth node n5.

The fifth switch element T5 is connected between the first node n1 and the third power line PL3. The fifth switch element T5 is turned on according to a gate-on voltage VGL of a second-1 common gate signal EM1 and connects a first node n1 to a third power line PL3. The fifth switch element T5 includes a first electrode connected to the first node n1, a gate electrode to which the second-1 common gate signal EM1 is applied, and a second electrode connected to the third power line PL3.

A sixth switch element T6 is connected between a third node n3 and a fourth node n4. The sixth switch element T6 is turned on according to a gate-on voltage VGL of a second-2 common gate signal EM2 and connects the third node n3 to the fourth node n4. The sixth switch element T6 includes a first electrode connected to the third node n3, a gate electrode to which the second-2 common gate signal EM2 is applied, and a second electrode connected to the fourth node n4.

A seventh switch element T7 is connected between the third node n3 and a fifth node n5. The seventh switch element T7 is turned on according to a gate-on voltage VGL of a second-3 common gate signal EM3 and connects the third node n3 to the fifth node n5. The seventh switch element T7 includes a first electrode connected to the third node n3, a gate electrode to which the second-3 common gate signal EM3 is applied, and a second electrode connected to the fifth node n5.

The capacitor Cst is connected between the first node n1 and the second node n2. The capacitor Cst maintains the gate-to-source voltage Vgs of the driving element DT during a light-emission period.

Gate signals applied to the pixel circuit of the second implementation include a first gate signal SCAN1(N), a first common gate signal SCAN2, a second-1 common gate signal EM1, a second-2 common gate signal EM2, and a second-3 common gate signal EM3. In the pixel circuit of the second implementation, the first common gate signal SCAN2, the second-1 common gate signal EM1, the second-2 common gate signal EM2, and the second-3 common gate signal EM3, excluding the first gate signal SCAN1(N), may be applied through common lines.

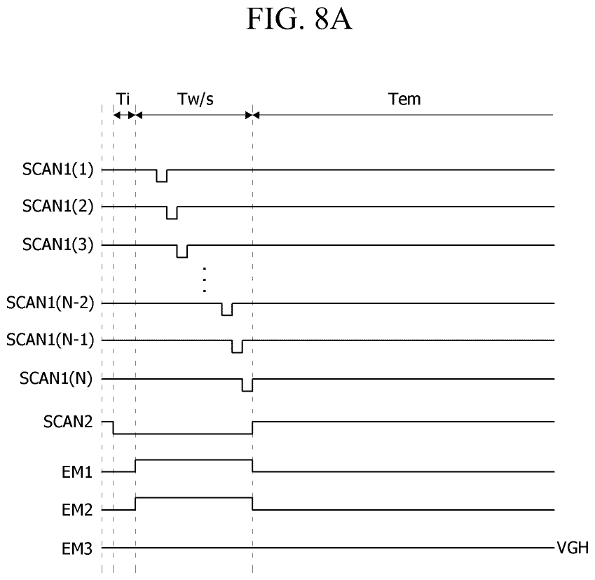

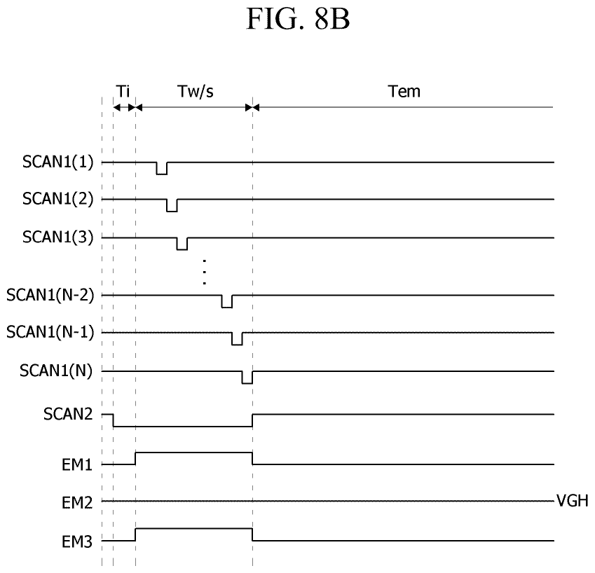

FIGS. 8A to 8B are diagrams showing driving timings of gate signals applied to the pixel circuit of FIG. 7.

Referring to FIG. 7 and FIGS. 8A to 8B, the pixel circuit according to an implementation of the present disclosure may be driven in the order of an initialization step Ti, a data writing and sensing step Tw/s, and a light-emission step Tem.

In the initialization step Ti, the first common gate signal SCAN2 having a gate-on voltage is applied (e.g., simultaneously) to all pixels through a first common line, and the second-1 common gate signal EM1 having a gate-on voltage may be simultaneously applied to all pixels through a second common line. In the case of a first mode, the second-2 common gate signal EM2 having a gate-on voltage may be simultaneously applied to all pixels through a third common line, and in the case of a second mode, the second-3 common gate signal EM3 having a gate-on voltage may be simultaneously applied to all pixels through a fourth common line.

In the data writing and sensing step Tw/s, the first gate signal SCAN1(1) to SCAN1(N) having a gate-on voltage may be sequentially applied to each pixel line.

In the light-emission step Tem, the second-1 common gate signal EM1 having a gate-on voltage may be simultaneously applied to all pixels through the second common line. In the case of the first mode, together with FIG. 8A, the second-2 common gate signal EM2 having a gate-on voltage is applied (e.g., simultaneously) to all pixels through a third common line, so that the first light-emitting elements of all pixels may simultaneously emit light. In the case of the second mode, as shown in FIG. 8B, the second-3 common gate signal EM3 having a gate-on voltage is applied (e.g., simultaneously) to all pixels through a fourth common line, so that the second light-emitting elements of all pixels may simultaneously emit light.

As such, in an implementation, excluding the first gate signal SCAN1(N) for applying a data voltage Vdata to each pixel line, the first common gate signal SCAN2, the second-1 common gate signal EM1, the second-2 common gate signal EM2, and the second-3 common gate signal EM3 may be simultaneously applied to all pixels through the first common line, the second common line, the third common line, and the fourth common line, respectively.

Accordingly, in an implementation, the entire display panel may be simultaneously switched between the first mode and the second mode.

In an implementation, since all pixels emit light simultaneously, instead of being sequentially emitted pixel line by pixel line, a section in which a gate-off voltage of the EM signal is applied becomes longer, and as a result, flicker may occur. Accordingly, in an implementation, it is intended to reduce a section in which a gate-off voltage of the EM signal is applied by distributing it.

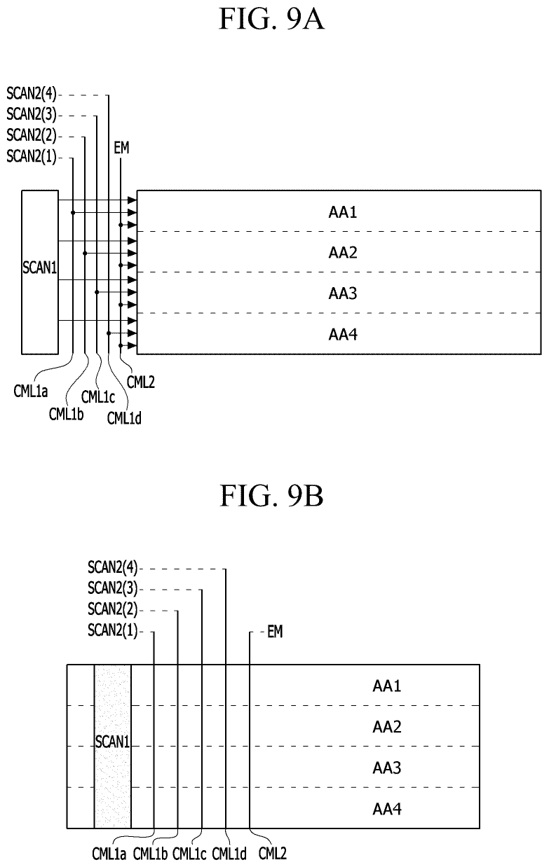

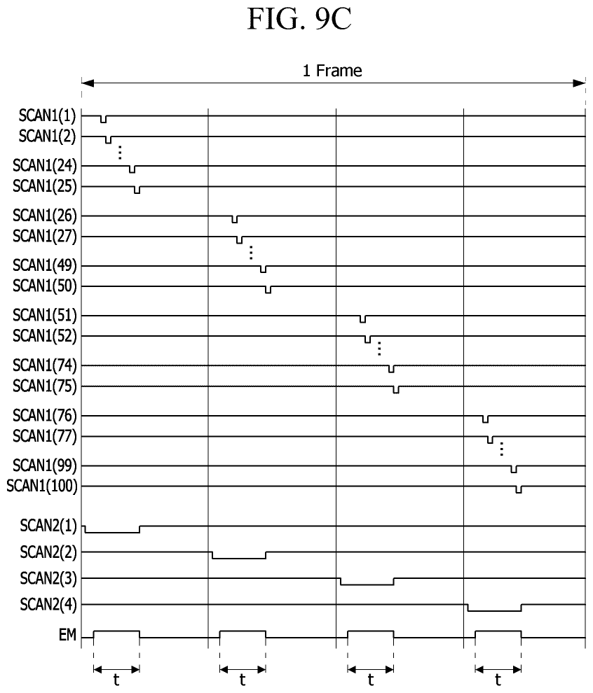

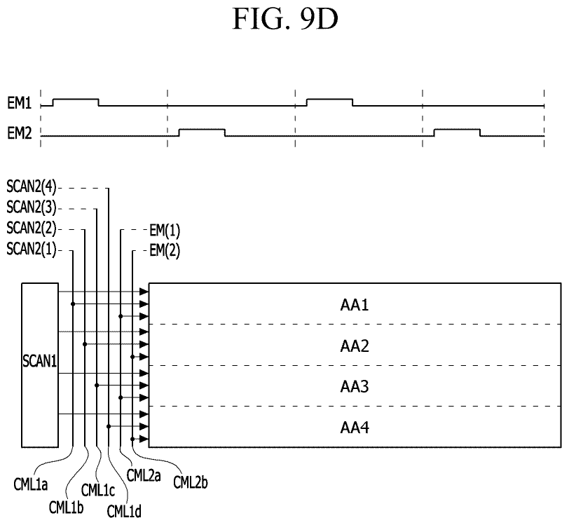

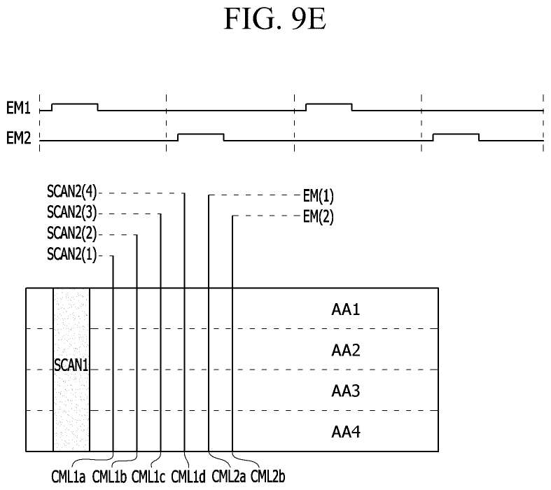

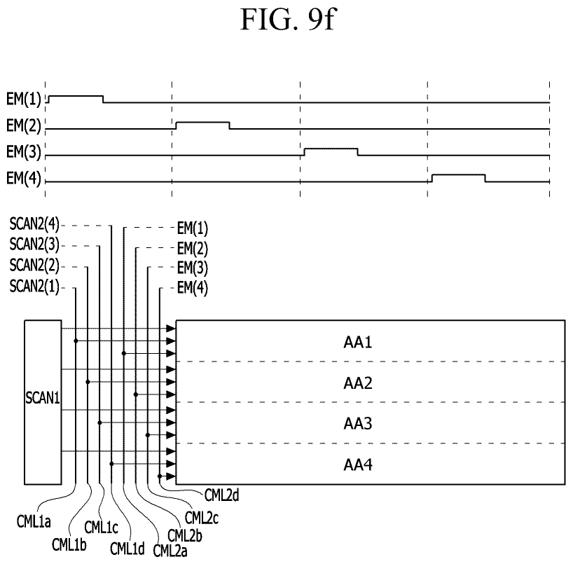

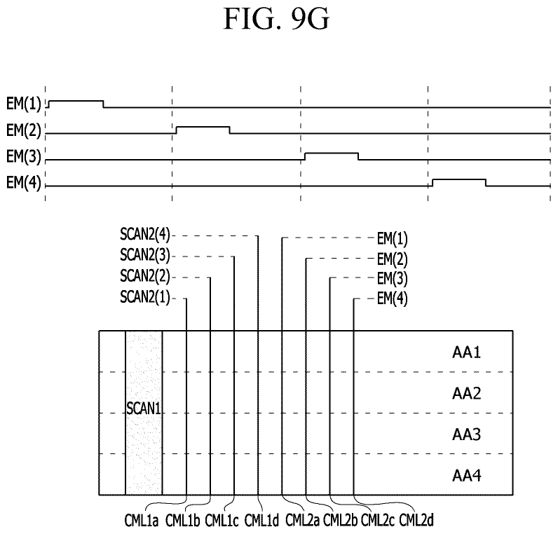

FIGS. 9A to 9G are diagrams for explaining the output principle of gate signals according to an implementation of the present disclosure.

Referring to FIGS. 9A to 9C, in an implementation, the display area is divided into a plurality of regions, and gate signals may be modulated and applied to cause simultaneous emission in each divided region.

For example, 100 pixel lines may be divided into four regions AA1, AA2, AA3, and AA4, and the second common gate signal EM may be applied to cause simultaneous emission in each region AA1, AA2, AA3, and AA4, each including 25 pixel lines.

The first gate signal SCAN1(N) may be sequentially applied on a pixel-line basis for each region AA1, AA2, AA3, and AA4.

The first common gate signals SCAN2(1) to SCAN2(4) may be simultaneously applied to the respective regions AA1, AA2, AA3, and AA4 through different first common lines CML1. That is, the first common gate signal SCAN2(1) is applied to a region AA1 through a first-a common line CML1a, the first common gate signal SCAN2(2) is applied to a region AA2 through a first-b common line CML1b, the first common gate signal SCAN2(3) is applied to a region AA3 through a first-c common line CML1c, and the first common gate signal SCAN2(4) is applied to a region AA4 through a first-d common line CML1d.

The second common gate signal EM may be applied through a single common line CML2 with modulated gate-on voltage pulses to cause simultaneous emission in in each region AA1, AA2, AA3, and AA4.

For example, when pixels in the entire area emit light simultaneously without dividing the regions, a section in which a gate-off voltage of the second common gate signal EM is applied during one frame is maintained for a time of tx4; however, when the regions are divided and pixels emit light simultaneously by region, the section in which the gate-off voltage of the second common gate signal EM is applied during one frame is maintained for only a time t for each region, so that flicker is not perceived.

In this example, the case where the second common gate signal EM is applied through a single common line is described, but it is not necessarily limited thereto, and a plurality of common lines may be applied.

Referring to FIGS. 9D to 9E, in an implementation, the second common gate signal EM may be applied by region through two second common lines CML2, that is, a second-a common line CML2a and a second-b common line CML2b.

For example, the second common gate signal EM(1) is simultaneously applied by region to odd-numbered regions AA1 and AA3, and the second common gate signal EM(2) is simultaneously applied by region to even-numbered regions AA2 and AA4.

When the second common gate signal EM is simultaneously applied by region through two second common lines in this manner, the light-emission time of the pixels in each region within one frame may be increased.

Referring to FIGS. 9F to 9G, in an implementation, the second common gate signal EM may be applied by region through four second common lines CML2, that is, a second-a common line CML2a, a second-b common line CML2b, a second-c common line CML2c, and a second-d common line CML2d.

For example, the second common gate signal EM(1) is applied to region AA1 through the second-a common line CML2a, the second common gate signal EM(2) is applied to region AA2 through the second-b common line CML2b, the second common gate signal EM(3) is applied to region AA3 through the second-c common line CML2c, and the second common gate signal EM(4) is applied to region AA4 through the second-d common line CML2d.

When the second common gate signal EM is simultaneously applied by region through four second common lines in this manner, the light-emission time of the pixels in each region within one frame may be increased.

In addition, in an implementation, at least one second common line to which the second common gate signal EM is applied may be employed, and the maximum number of second common lines may be equal to the number of divided regions. Accordingly, in an implementation, when the display area is divided into n regions (where n is a natural number), the number of first common lines to which second gate signals for initializing the pixels in each region are applied may be n, and the number of second common lines to which third gate signals for causing the light-emitting elements in the pixels of each region to emit light are applied may be set within a range of 1 to n.

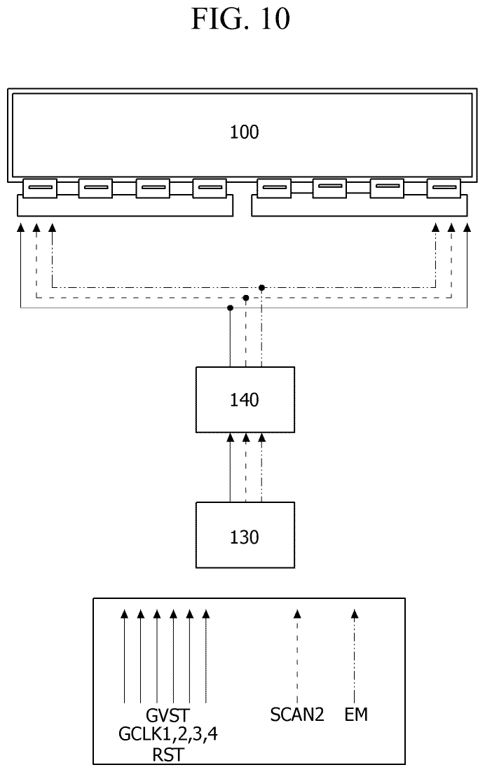

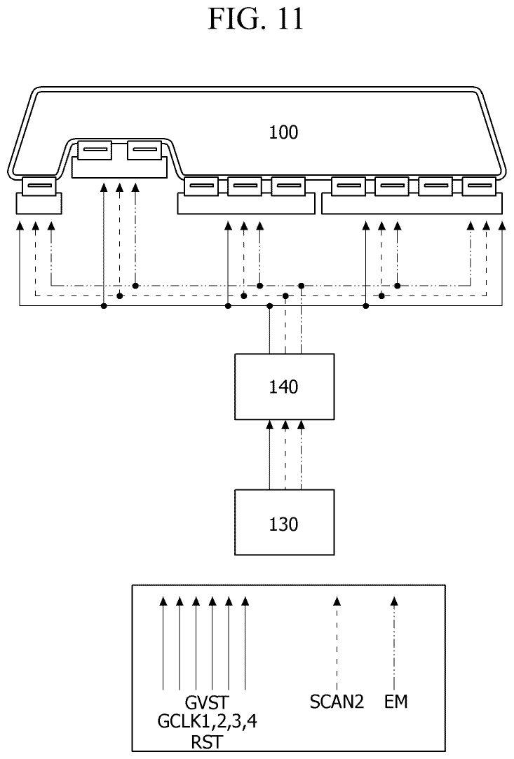

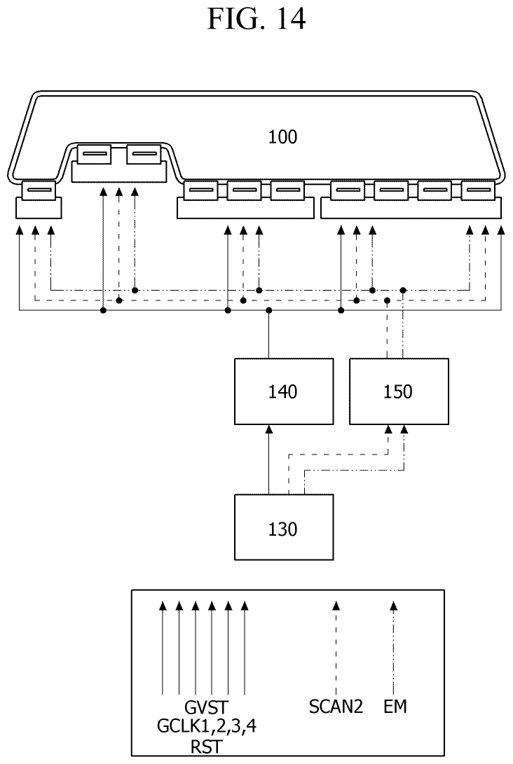

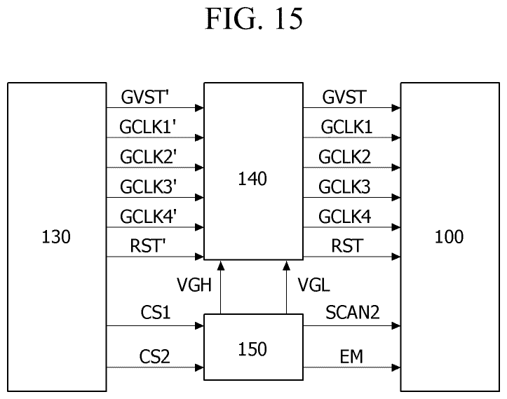

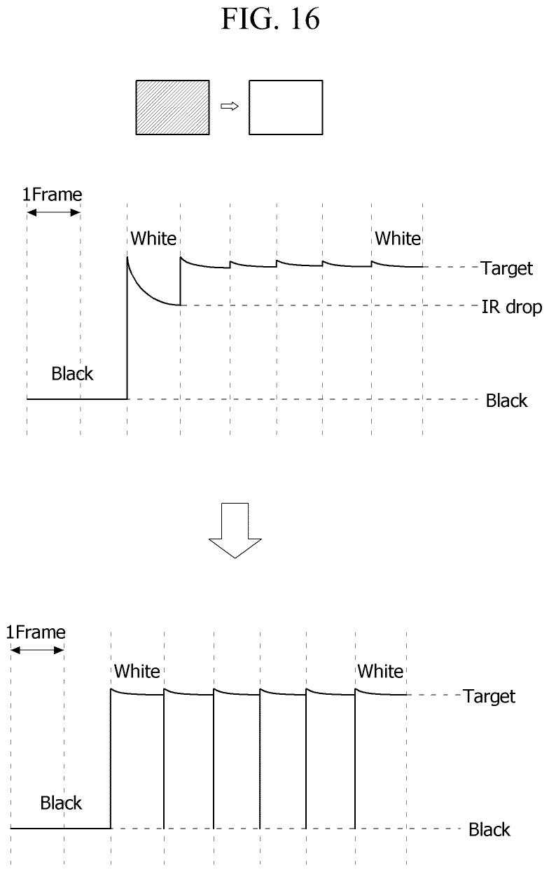

FIGS. 10 to 15 are diagrams for explaining the gate signal application principle according to an implementation.

Referring to FIGS. 10 to 12, a timing controller 130 according to the implementation may generate a start signal GVST′, clock signals GCLK1′, GCLK2′, GCLK3′, and GCLK4′, and a reset signal RST′ for generating a first gate signal SCAN1(N), and also generate a first common gate signal SCAN2′ and a second common gate signal EM′ and provide them to a level shifter 140.

The level shifter 140 may amplify voltage levels of a start signal GVST′, clock signals GCLK1′, GCLK2′, GCLK3′, and GCLK4′, a reset signal RST′, a first common gate signal SCAN2′, and a second common gate signal EM′ provided from the timing controller 130, and may supply the amplified start signal GVST, clock signals GCLK1, GCLK2, GCLK3, and GCLK4, and reset signal RST to the first gate driver 120, may supply the first common gate signal SCAN2 to the first common line CML1, and may supply the second common gate signal EM to the second common line CML2.

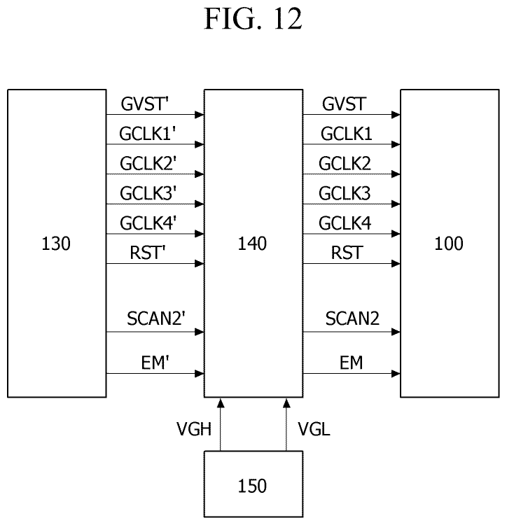

As shown in FIG. 12, a power supply 150 may supply a high-potential voltage VGH and a low-potential voltage VGL to the level shifter 140 for amplifying the voltage levels of the signals in the level shifter 140.

That is, in an implementation, the timing controller may generate a first common gate signal and a second common gate signal and may apply them to pixels in a display area through a first common line and a second common line.

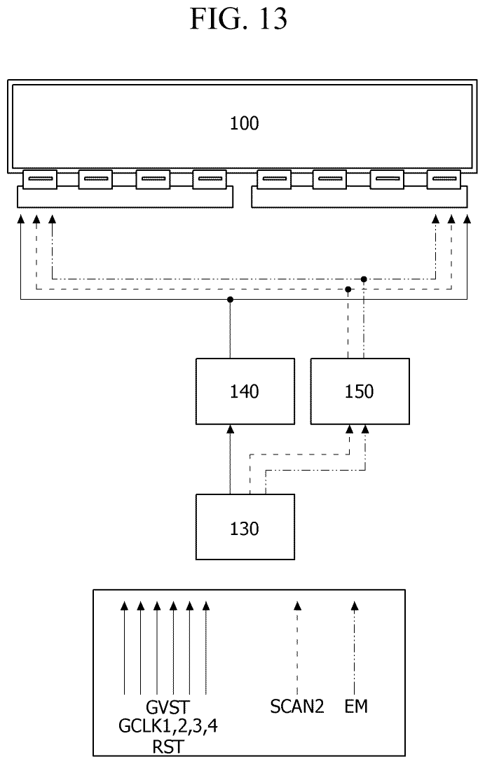

Referring to FIGS. 13 to 15, a timing controller 130 according to the implementation may generate a start signal GVST′, clock signals GCLK1′, GCLK2′, GCLK3′, and GCLK4′, and a reset signal RST′ for generating a first gate signal SCAN1(N), and may provide them to a level shifter 140.

The level shifter 140 may amplify the voltage levels of the start signal GVST′, clock signals GCLK1′, GCLK2′, GCLK3′, and GCLK4′, and the reset signal RST′ provided from the timing controller 130, and may supply the amplified start signal GVST, clock signals GCLK1, GCLK2, GCLK3, and GCLK4, and reset signal RST to the first gate driver 120.

In addition, the timing controller 130 according to the implementation may provide a first control signal CS1 and a second control signal CS2 to a power supply 150, and the power supply 150 may generate a first common gate signal SCAN2 based on the first control signal CS1 and may supply the generated first common gate signal SCAN2 to the first common line CML1, and may generate a second common gate signal EM based on the second control signal CS2 and may supply the generated second common gate signal EM to the second common line CML2.

That is, in an implementation, the power supply may generate a first common gate signal and a second common gate signal and may apply them to pixels in the display area through a first common line and a second common line.

In addition, in an implementation, the TFTs of a pixel circuit in which all elements are implemented as p-channel LTPS TFTs may have a hysteresis characteristic. Due to the hysteresis characteristic, when a data voltage changes from a black grayscale to a white grayscale, a threshold voltage Vth may decrease, and as a result, luminance may decrease more significantly than when the voltage changes from a white grayscale to another white grayscale without a change in the threshold voltage, causing degradation in first frame response (FFR) performance.

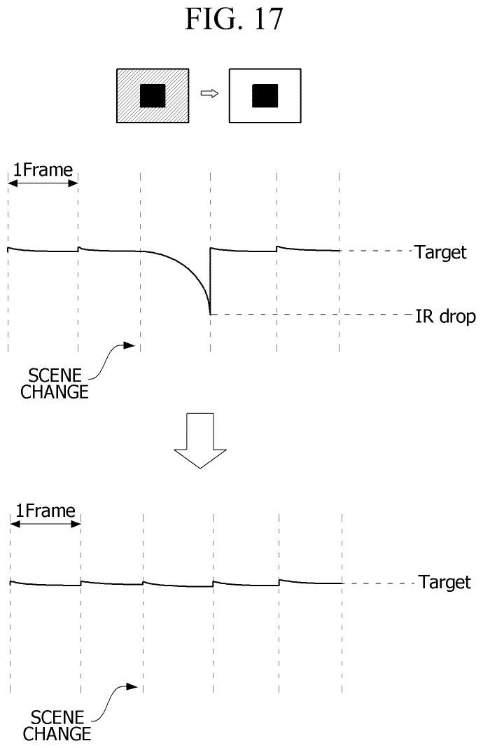

FIGS. 16 to 17 are diagrams showing improvement in FFR performance according to an implementation of the present disclosure.

Referring to FIG. 16, in a comparative example in which simultaneous light emission is not performed, when the grayscale changes from white to black, a voltage drop in the pixel driving voltage may not occur; however, when the grayscale changes from black to white, the voltage drop in the pixel driving voltage may increase, causing the luminance of the light-emitting pixels to decrease, thereby degrading the FFR performance.

In contrast, in an implementation in which simultaneous light emission is performed, since all pixels emit light after a data voltage is applied to all pixels within one frame, a voltage drop in the pixel driving voltage may not occur, thereby improving the FFR performance.

Referring to FIG. 17, when a grayscale area is fixed and a surrounding area changes from a black grayscale to a white grayscale, in the comparative example in which simultaneous light emission is not performed, a voltage drop in the pixel driving voltage may decrease, causing the luminance of the light-emitting pixels to increase, thereby generating a bright-type flicker.

In addition, when a grayscale area is fixed and a surrounding area changes from a white grayscale to a black grayscale, in a comparative example in which simultaneous light emission is not performed, a voltage drop in the pixel driving voltage may increase, causing the luminance of the light-emitting pixels to decrease, thereby generating a dark-type flicker.

In contrast, in an implementation in which simultaneous light emission is performed, since all pixels emit light after a data voltage is applied to all pixels within one frame, a voltage drop in the pixel driving voltage may not occur, and flicker may not be generated during screen transitions.

As such, in an implementation, since a data voltage is applied to all pixels within one frame and then light emission is simultaneously performed, image quality degradation such as FFR performance deterioration or flicker may be improved.

Although the implementations of the present disclosure have been described in more detail with reference to the accompanying drawings, the present disclosure is not limited thereto and may be embodied in many different forms without departing from the technical concept of the present disclosure. Therefore, the implementations disclosed in the present disclosure are provided for illustrative purposes only and are not intended to limit the technical concept of the present disclosure. The scope of the technical concept of the present disclosure is not limited thereto. Therefore, it should be understood that the above-described implementations are illustrative in all aspects and do not limit the present disclosure.

What is claimed is:

1. A display device comprising:
a pixel array in which a plurality of data lines, a plurality of gate lines, and a plurality of pixel circuits are arranged;
a data driver configured to output a data voltage to the plurality of data lines;
a gate driver configured to sequentially output gate signals to the plurality of gate lines;
a common line configured to simultaneously apply a common gate signal to the plurality of gate lines; and
a timing controller configured to generate the common gate signal.

2. The display device according to claim 1, wherein the gate signal includes a first scan signal for supplying the data voltage to the pixel circuits.

3. The display device according to claim 2, wherein the common gate signal includes:
a second scan signal for initializing the pixel circuits; and
an emission control signal for driving light-emitting elements of the pixel circuits.

4. The display device according to claim 3, wherein the pixel array is divided into n regions, where n is a natural number, and
wherein the common line includes:
n common lines for applying the second scan signal to the respective n regions, and
one common line for applying the emission control signal to the n regions.

5. The display device according to claim 4, wherein the number of common lines for applying the emission control signal is less than or equal to n.

6. The display device according to claim 1, wherein the gate driver and the common line are arranged in a non-display area or a display area and are connected to the plurality of gate lines.

7. The display device according to claim 1, wherein the pixel circuit includes a driving element, a first switch element, a second switch element, switch element, a fourth switch element, and a fifth switch element, a light-emitting element, and a capacitor,
the driving element includes a gate electrode connected to a second node, a first electrode connected to a first power line to which a pixel driving voltage is applied, and a second electrode connected to a third node,
the first switch element includes a gate electrode to which a first scan signal is applied, a first electrode connected to a data line to which a data voltage is applied, and a second electrode connected to a first node,
the second switch element includes a gate electrode to which a second scan signal is applied, a first electrode connected to the second node, and a second electrode connected to the third node,
the third switch element includes a gate electrode to which the second scan signal is applied, a first electrode connected to a third power line to which a reference voltage is applied, and a second electrode connected to a fourth node,
the fourth switch element includes a gate electrode to which an emission control signal is applied, a first electrode connected to the first node, and a second electrode connected to the third power line,
the fifth switch element includes a gate electrode to which the emission control signal is applied, a first electrode connected to the third node, and a second electrode connected to the fourth node,
the light-emitting element is connected between the fourth node and a second power line to which a pixel base voltage is applied, and
the capacitor is connected between the first node and the second node.

8. The display device according to claim 1, wherein the pixel circuit includes a driving element, a first switch element, a second switch element, a third switch element, a fourth switch element, a fifth switch element, a sixth switch element, and a seventh switch element, a first light-emitting element and a second light-emitting element, and a capacitor,
the driving element includes a gate electrode connected to a second node, a first electrode connected to a first power line to which a pixel driving voltage is applied, and a second electrode connected to a third node,
the first switch element includes a gate electrode to which a first scan signal is applied, a first electrode connected to a data line to which a data voltage is applied, and a second electrode connected to a first node,
the second switch element includes a gate electrode to which a second scan signal is applied, a first electrode connected to the second node, and a second electrode connected to the third node,
the third switch element includes a gate electrode to which the second scan signal is applied, a first electrode connected to a third power line to which a reference voltage is applied, and a second electrode connected to a fourth node,
the fourth switch element includes a gate electrode to which the second scan signal is applied, a first electrode connected to the third power line, and a second electrode connected to a fifth node,
the fifth switch element includes a gate electrode to which a first emission control signal is applied, a first electrode connected to the first node, and a second electrode connected to the third power line,
the sixth switch element includes a gate electrode to which a second emission control signal is applied, a first electrode connected to the third node, and a second electrode connected to the fourth node,
the seventh switch element includes a gate electrode to which a third emission control signal is applied, a first electrode connected to the third node, and a second electrode connected to the fifth node,
the first light-emitting element is connected between the fourth node and a second power line to which a pixel base voltage is applied,
the second light-emitting element is connected between the fifth node and the second power line, and
the capacitor is connected between the first node and the second node.

9. The display device according to claim 1, wherein the pixel circuits are driven in the order of an initialization step, a data writing and sensing step, and a light-emission step,
in the initialization step, the pixel circuits are simultaneously initialized by the common gate signal,
in the data writing and sensing step, a data voltage is sequentially applied to the pixel circuits on a pixel-line basis by the gate signal, and
in the light-emission step, the pixel circuits simultaneously emit light by the common gate signal.

10. A display device comprising:
a pixel array in which a plurality of data lines, a plurality of gate lines, and a plurality of pixel circuits are arranged;
a data driver configured to output a data voltage to the plurality of data lines;
a gate driver configured to sequentially output gate signals to the plurality of gate lines;
a common line configured to simultaneously apply a common gate signal to the plurality of gate lines; and
a power supply configured to generate the common gate signal.

11. A display device according to claim 10, wherein the gate signal includes
a first scan signal for supplying the data voltage to the pixel circuits.

12. A display device according to claim 11, wherein the common gate signal includes:
a second scan signal for initializing the pixel circuits; and
an emission control signal for driving light-emitting elements of the pixel circuits.

13. A display device according to claim 12, wherein the pixel array is divided into n regions, where n is a natural number, and
the common line includes:
n common lines for applying the second scan signal to each of the respective n regions, and
one common line for applying the emission control signal to the n regions.

14. A display device according to claim 13, wherein the number of common lines for applying the emission control signal is less than or equal to n.

15. A display device according to claim 10, further comprising:
a timing controller configured to generate a control signal for generating the common gate signal,
wherein the power supply generates the common gate signal based on the control signal.
